(19) United States
(12) Patent Application Publication
(10) Pub. No.: US 2008/0043416 A1
(43) Pub. Date: Feb. 21, 2008

(54) Method and apparatus for hands free wearable computer

(76) Inventor: Shankar Narayan, Redwood City, CA (US)

Correspondence Address: Shankar Narayan, 392 Roble Ave, Redwood City, CA, 94061, US

(21) Appl. No.: 11/504,393

(22) Filed: Aug. 15, 2006

(51) Int. Cl. G06F 1/16; H05K 5/00

(52) U.S. Cl. 361/683; 361/679; 345/7; 345/169; 359/630; 708/139

(57) ABSTRACT

A hands free wearable computer is provided. The hands free wearable computer includes an adjustable display tray, a split hands free two-hand foldable integrated input device that can be carried by gripping it, a video camera. The split hands free two-hand foldable integrated input device that can be carried can be used with the wearable computer as well as other non-wearable computer such as desktops, servers, laptops and entertainment devices such as game consoles, televisions. The hands free wearable computer with a hands free integrated input device is easy to wear and use while standing, sitting, laying down in a bed, walking, driving a car etc. while permitting a user's hands to become free to perform any other tasks that need to be attended to by the user's hands.

### RELATED APPLICATIONS

This application claims priority to provisional U.S. application Ser. No. 60/713,925, filed Sep. 2, 2005.

### FIELD OF THE INVENTION

The present invention relates to the field of wearable computers. More particularly, the present invention relates to providing a hands free wearable computer and a grip and carry foldable hands free two-hand integrated input device that is easy to use and carry.

### BACKGROUND OF THE INVENTION

A need exists for wearable computers that are easy wear and use. The problems with wearable computers include: difficulty to put them on, difficulty to take them off, difficulty to use them in day to day usage situations such as sitting, standing, laying down in a bed, walking, shopping, driving in a car etc. A glaring difficulty in using wearable computers is the unusable input devices that provide the functionality provided by keyboards, mouse, game controllers, scroll wheels, remote controls etc. These input devices due to lack of space either eliminate some of the keys and functions or they make it very difficult to generate the input by requiring user to chord a combination of keys. For people that are familiar with a particular keyboard layout such as QWERTY or DVORAK, using chording keyboards is not an acceptable option. Another challenge with input devices with wearable computers is that the input devices sometimes are attached to the hands of the user in such a way that it is cumbersome to free the users hands to perform any task that requires free hands. This effectively limits the usefulness of hands. Also, the fact that the input device is tied to the hand reduces the degree of flexibility of the fingers to strike the keys vigorously leading to lack of force feedback and tactile sensation causing ergonomic discomfort, hardship in typing, reducing the speed of typing. In most computing devices used for entertainment and otherwise, it is desired by users to have their hands free so that users can do anything they want to do with their hands even during their sessions of use with their computers and entertainment devices. This is true with keyboards, mouse, remote controls, game controllers and such input devices that are traditionally used with computers and entertainment devices. Users desire a design of a wearable computer with a hands free integrated input device. Such a device would improve their ergonomic comfort in using the wearable computer as well as traditional computing and entertainment devices using the hands free input device. Even when a user is sitting in front of a computer, the user need not stay fixed in one posture in one direction, as the display direction changes along with the user as the user changes direction in their chair. This results in significant ergonomic comfort. Also, when the user attaches a video camera and a wired or wireless internet connection, they can use the apparatus as a video phone which does not limit their mobility as the camera is always pointed to the face of the person using better than any face tracking hardware that is helpless once the user turns their back to the camera. Another challenge with wearable computers has been that they are not easy to carry when they are not in use. Being able to carry the wearable computer either close to chest, as a shoulder bag or backpack depending on the convenient way to carry at any given point in time is of paramount significance to the users of wearable computers. It would also be desirable to use the same input device with any computer or an entertainment device that they want to use.

### SUMMARY OF THE INVENTION

A hands free wearable computer is provided. The hands free wearable computer includes an adjustable display tray, a split hands free two-hand foldable integrated input device that can be carried by gripping it, a video camera. The split hands free two-hand foldable integrated input device that can be carried includes a right hand foldable integrated input device that can be carried and a left hand foldable integrated input device that can be carried. The adjustable display tray comprises a container to hold a display device such as a tablet computer. The adjustable display tray is held to the body with a belt and suspender body harness. The split hands free two-hand foldable integrated input device has a length adjustable clip and a cord system. The length adjustable clip and cord system of each of the two split hands free two-hand foldable integrated input device is used to suspend the foldable integrated input device for each hand from each side of the belt that is used to carry the foldable integrated input device. The foldable integrated input device does not need to be worn or held to key in the input. The hands free wearable computer with a hands free integrated input device is easy to wear and use while standing, sitting, laying down in a bed, walking, driving a car etc. while permitting a user's hands to become free to perform any other tasks that need to be attended to by the user's hands. The integrated input device ensures that the same fingers that are used by users of QWERTY/DVORAK keyboards are used to strike the corresponding keys in the integrated input device, such as using the thumb to strike the space bar.

### BRIEF DESCRIPTION OF THE DRAWINGS

FIG. 1 is a front view of a hands free wearable computer without the grip and carry foldable hands free two-hand integrated input device.

FIG. 2 is a top view of a display tray.

FIG. 3 is a bottom view of a display tray.

FIG. 4 is a perspective view from right side of a right hand grip and carry foldable hands free integrated input device.

FIG. 5 is a bottom view of a right hand grip and carry foldable hands free integrated input device.

FIG. 6 is a perspective view of display tray with the grip and carry foldable hands free-integrated input devices secured to the display tray.

FIG. 7 is a perspective view from right side of a right hand grip and carry foldable hands free integrated input device that is folded.

FIG. 8 is a perspective view from left side of a right hand grip and carry foldable hands free integrated input device.

FIG. 9 is a front view of a person wearing a hands free wearable computer using while standing.

FIG. 10 is a side view of a person wearing a hands free wearable computer using while standing.

FIG. 11 is a side view of a person carrying a hands free wearable computer close to their chest.

FIG. 12 is a side view of a person carrying a hands free wearable computer like a shoulder bag.

FIG. 13 is a side view of a person carrying a hands free wearable computer like a backpack.

FIG. 14 is a front view of a car steering wheel with a stand for integrated input device on top of the wheel.

FIG. 15 is a side view of a man with the suspender of the hands free wearable computer attached to a chair hook.

FIG. 16 is a back view of a man wearing an alternate embodiment of the hands free wearable computer that can be carried only close to wearer's chest.

FIG. 17 is a perspective view from right side of a right hand grip and carry hands free integrated input device an alternate embodiment of the input device.

### DETAILED DESCRIPTION OF THE PREFERRED EMBODIMENT

The present invention will now be described in detail with reference to a preferred embodiment thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well-known process steps and/or structures have not been described in detail in order to not unnecessarily obscure the present invention.

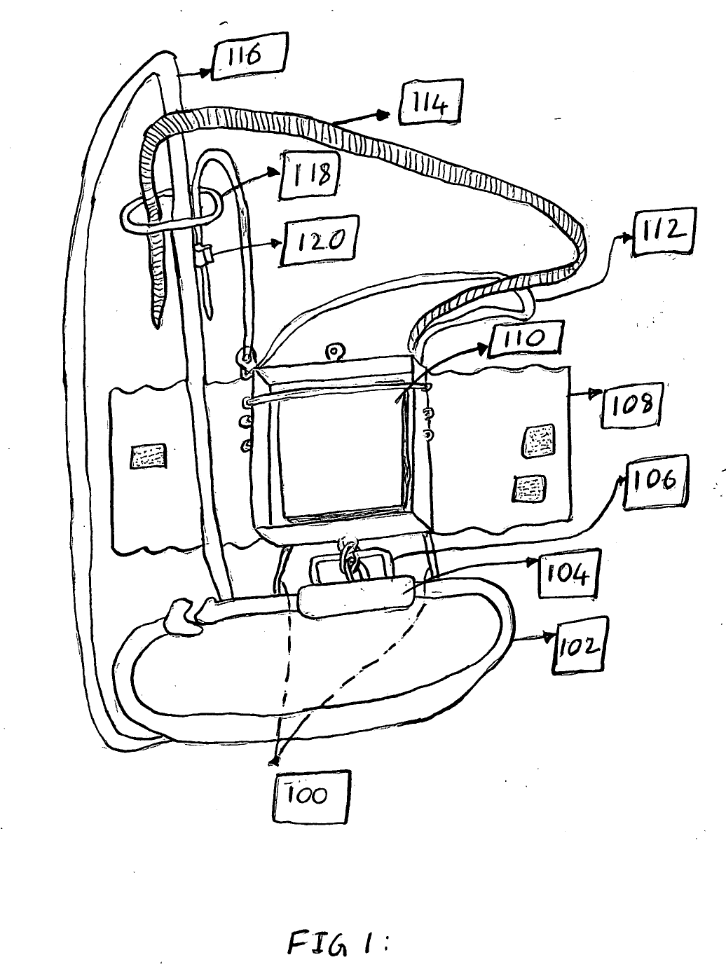

Referring FIG. 1 is a front view of a hands free wearable computer without the grip and carry foldable hands free two-hand integrated input device. Reference numeral 108 is the display tray that holds a permanently fixed display device referenced by reference numeral 110. The display tray 108 is connected to a belt shown by reference numeral 102. The belt shown by reference numeral 102 is part of a belt and suspender body harness. A sliding lengthwise loop that slides around the belt referenced by numeral 104 is used to slide the display to any part of the belt. The sliding length wise loop that slides around the belt has a cloth handle referenced by reference numeral 106. The length wise loop is attached to the bottom middle of the display tray. A small rope referenced by numeral 112 is used to adjust the distance of the display from the wearer's body. Two cloth snaps are used to secure the two bottom ends to the belt when the wearer is wearing the hands free wearable computer for use and not to carry it as a shoulder bag or a back pack. The small rope referenced by numeral 112 starts from the front of the person and it then goes behind the back of the person below the right arm and comes over the left shoulder from behind to go through a one eyed pulley system to eventually pass through a small rope clip referenced by numeral 120 sewn on the suspender referenced by numeral 116. The suspender referenced by numeral 120 is securely sewn to the belt in the front and the back side. A large rope referenced by numeral 114 is also attached to the top right corner of the display tray and goes behind the back from underneath the wearers right arm and comes over the left shoulder from behind. This large rope is used to carry the wearable computer like a backpack.

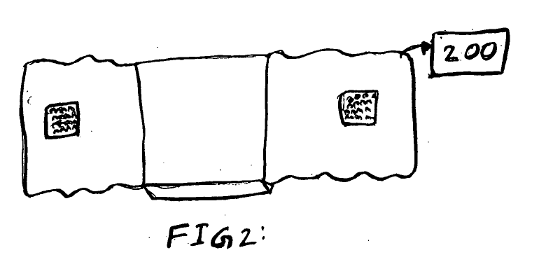

Referring FIG. 2 is a bottom view of the display tray. It also shows the flaps attached to the display tray referenced by numeral 200. The flaps are used to secure the grip and carry foldable hands free two-hand integrated input device.

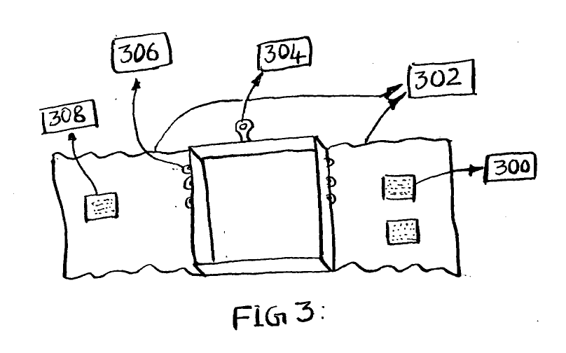

Referring FIG. 3 is a top view of display tray. Velcro™ referenced by numeral 300 are the place holders for securing the grip and carry foldable hands free two-hand integrated input device to the display tray. Flaps 300 are bendable to close both the front of the display tray when the display is not in use and on the back of the display tray when the display is in use. A video camera 304 is secured on the middle top of the display tray that enables this wearable computer to be an ideal video phone device that is wearable and carryable. Several cloth loops 306 are affixed to the right and left side of the display tray frame to facilitate the securing of a loose display. Additional Velcro™ 308 is used to secure other peripherals that could be worn such as audio head sets to the bendable flaps of the display tray.

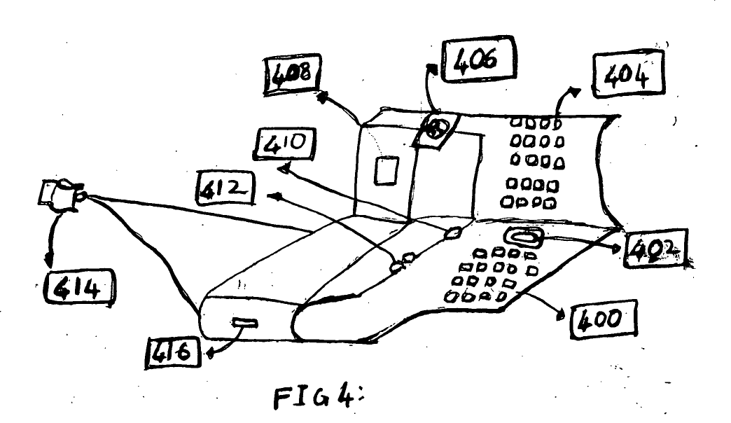

Referring FIG. 4 is a perspective view from right side of a right hand grip and carry foldable hands free integrated input device. QWERY/DVARAK keys for each hand 400 are laid out on the bottom surface of the hands free integrated input device. 402 scroll wheel is used for controlling the wireless enables embedded input device computer as well as the destination display device. Several additional keys 404 such as remote control keys, function keys etc are laid out on the side surface of the integrated input device. A game controller tab 406 is fixed to the edge of the lining for gripping the integrated input device. 408 is a chamber for batteries and other components for the hands free integrated input device. A space bar key 410 is laid out on the lining to help the user strike the space bar key with the thumb as the users are experienced to do. Mouse buttons 412 are laid out underneath the lining so that the user that grips the integrated input device can curl their finger to click the mouse buttons for single and double clicking. A cord and clip system 414 to secure the integrated input device to the belt and the wearer when the wearer is walking is provided. USB port 416 is provided for connecting to display devices that are not wireless enabled. It could be any other alternative to USB.

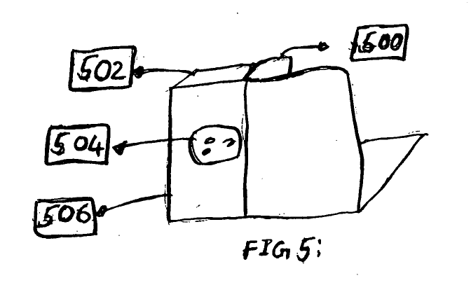

Referring FIG. 5 is a perspective view from right side of a right hand grip and carry foldable hands free integrated input device. Wrist pad 502 is used to support the wrists. A lining 500 is at the top of the wrist pad going along the contours of the integrated input device is used to grip the integrated input device. An optical mouse 504 is used to generate the mouse input. A chamber 506 is provided to encase a wireless enabled embedded input device computer.

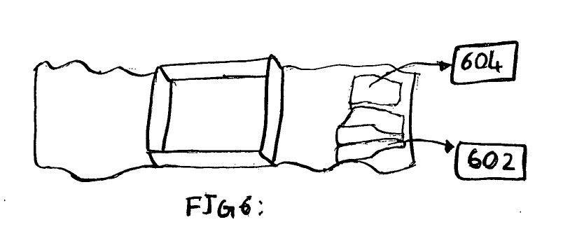

Referring FIG. 6 is a perspective view of display tray with the grip and carry foldable hands free integrated input devices secured to the display tray. Right hand grip and carry foldable hands free integrated input device 602 and left hand grip and carry foldable hands free integrated input device 604 can be secured to the flaps.

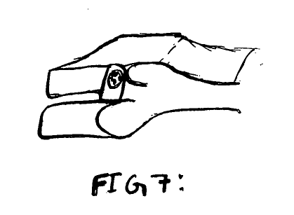

Referring FIG. 7 is a perspective view from right side of a right hand grip and carry foldable hands free integrated input device that is folded. When folded the hands free integrated input device reduces significantly in size.

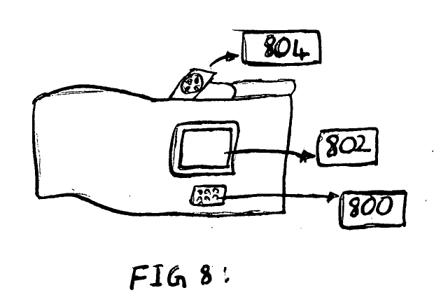

Referring FIG. 8 is a perspective view from left side of a right hand grip and carry foldable hands free integrated input device. The back surface of the grip and carry foldable hands free integrated input device contains a Velcro™ 800 patch for securing the integrated input device to the flaps of the display tray. The game controller tab 804 can be seen at the edge of the wrist pad. Lcd display 802 that shows the display devices in the wireless and wired neighborhood to permit the wearer to switch controlling different display devices using the grip and carry foldable hands free integrated input device.

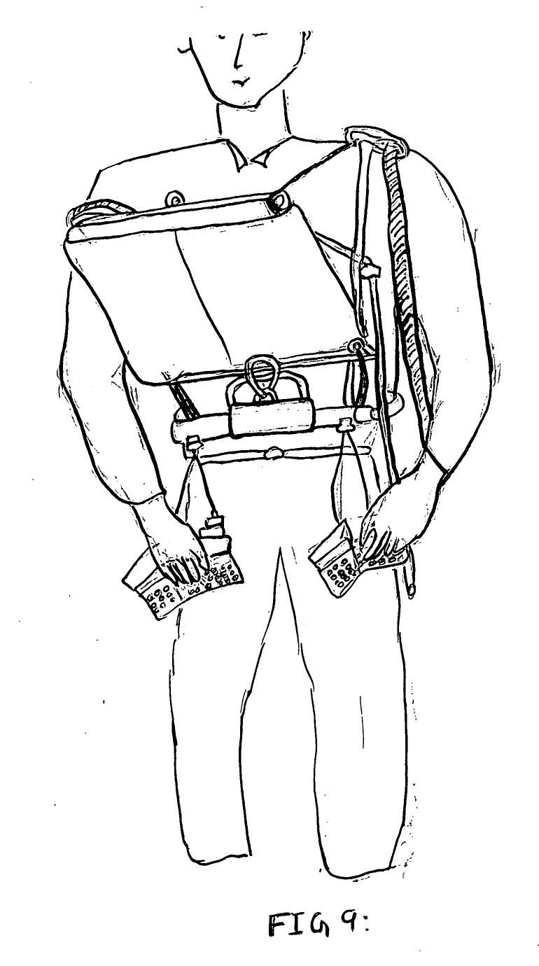

Referring FIG. 9 is a front view of a person wearing a hands free wearable computer using while standing. It can be seen that the wearer has hands available to perform other tasks besides operating the grip and carry foldable hands free integrated input device.

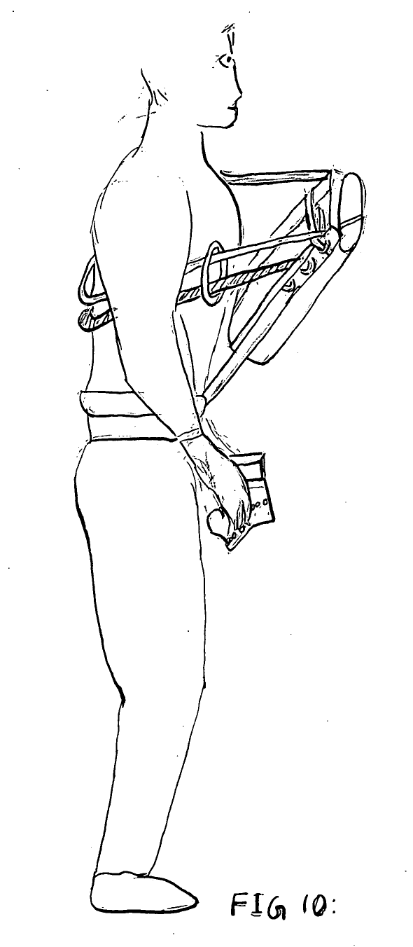

Referring FIG. 10 is a side view of a person wearing a hands free wearable computer using while standing. Here to is a picture of how a user can comfortably use the hands free wearable computer.

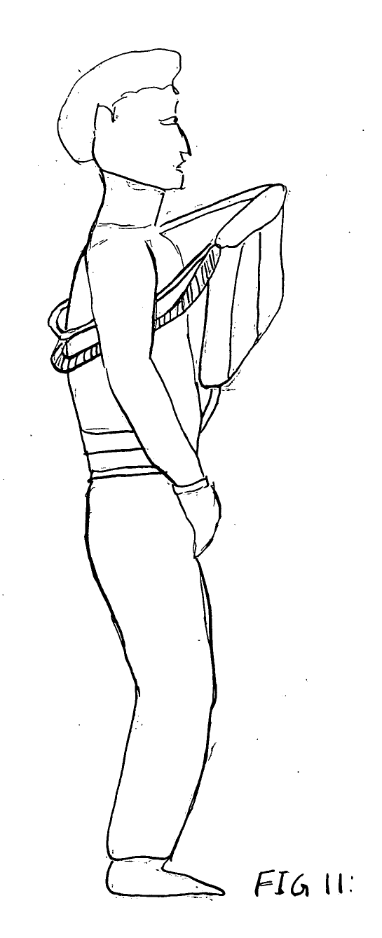

Referring FIG. 11 is a side view of a person carrying a hands free wearable computer close to their chest. When a user is not using the hands free wearable computer they can carry it on their person in one of three ways as convenient. The user may also choose to set the hands free wearable computer very easily by just releasing the belt buckle and taking the hands free wearable computer off with less difficulty than taking a shirt off. On of the ways the user can carry the wearable computer is by securing the grip and carry foldable hands free integrated input device to the flaps and closing the flaps over the display, and then release the small rope clip and pull the small rope to bring the display tray close to the chest of the user and then tighten the small rope clip. Once the display tray is pulled to a users chest the user can then walk about as they please.

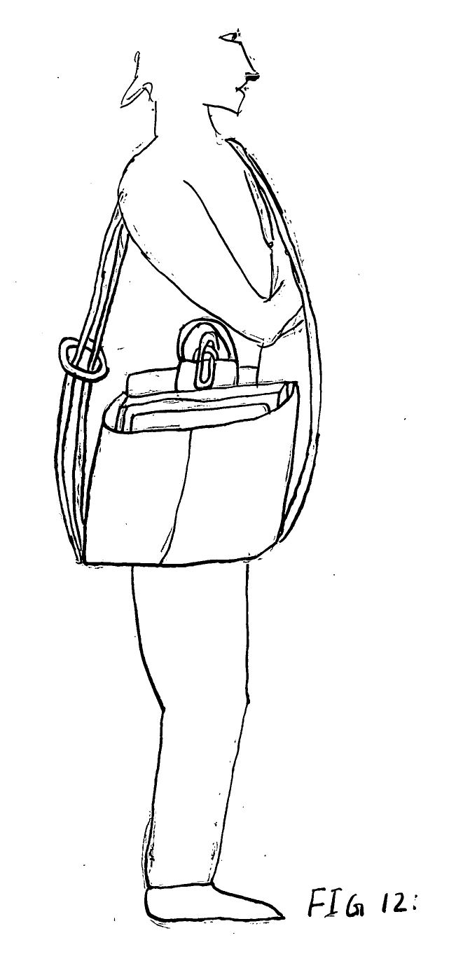

Referring FIG. 12 is a side view of a person carrying a hands free wearable computer like a shoulder bag. The wearer can also carry the hands free wearable computer as they would carry a shoulder bag. They can loosen small rope clip and release the small rope until the secured and closed display tray is hanging below the belt. At this point the user can release the two cloth snaps if they are being used, and then using the cloth handle move the display tray to the right side of the person along the belt. Once the display tray is to the side, a person can walk about as they would if they were carrying a shoulder bag.

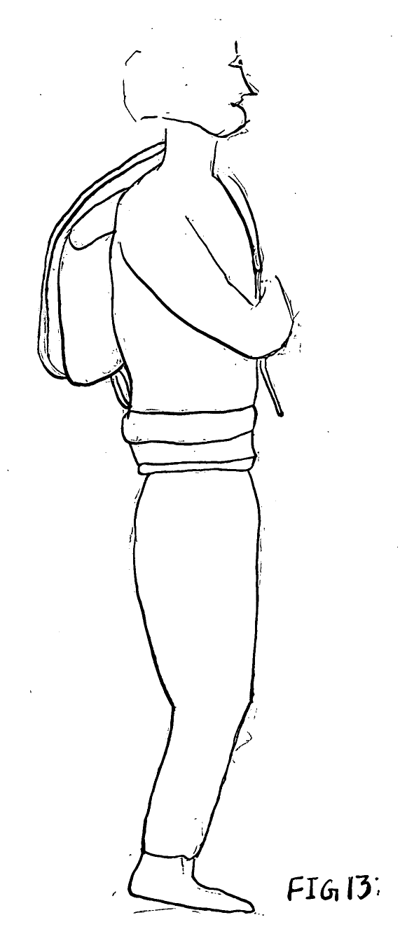

Referring FIG. 13 is a side view of a person carrying a hands free wearable computer like a backpack. Instead of just stopping at moving the display tray to the right side of the person along the belt, a user can continue to move it all the way to the back of their person and then pull the large rope down lifting the display tray behind the person. They can then secure the large rope to the belt and walk about as though they were carrying a backpack.

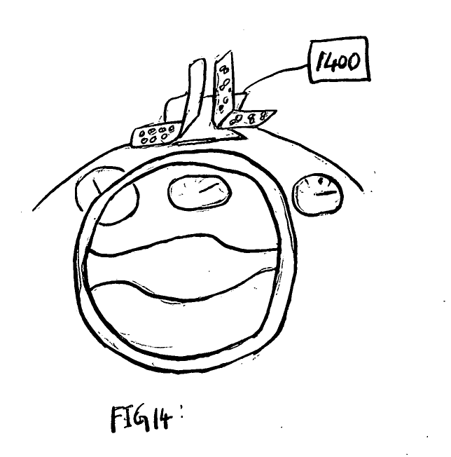

Referring FIG. 14 is a front view of a car steering wheel with a stand 1400 for integrated input device on top of the wheel. On the rear occasion when a user wants to use the hands free wearable computer in a car, a stand is provided just above the steering wheel to fix the hands free integrated input device to the stand. The user can enter input when the users hands are aligned with the hands free integrated input device, and take their hands off to operate the steering wheel and other controls whenever they need to. In future, it is desirable to place all the controls in a car to be operated with the hands free integrated input device.

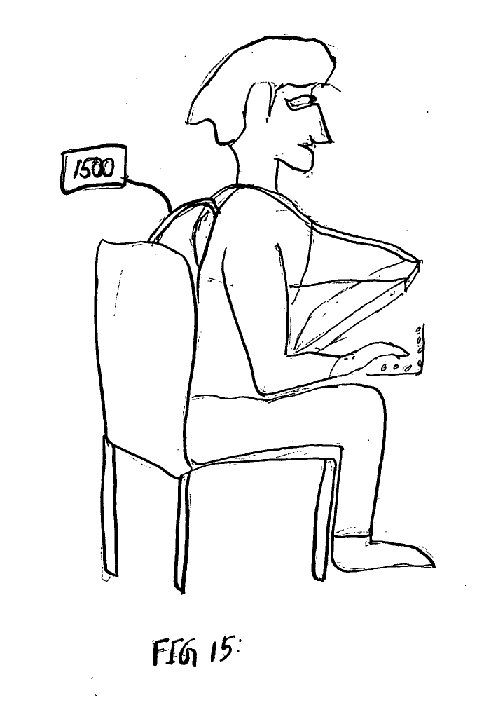

Referring FIG. 15 is a side view of a man with the suspender of the hands free wearable computer attached to a chair hook. When sitting on a chair it might at times be convenient to let the chair support the display tray instead of the wearer's shoulder and body. A pair of chair hooks 1500 are provided to hook the back side ropes on the right side and the left side to the chair hooks.

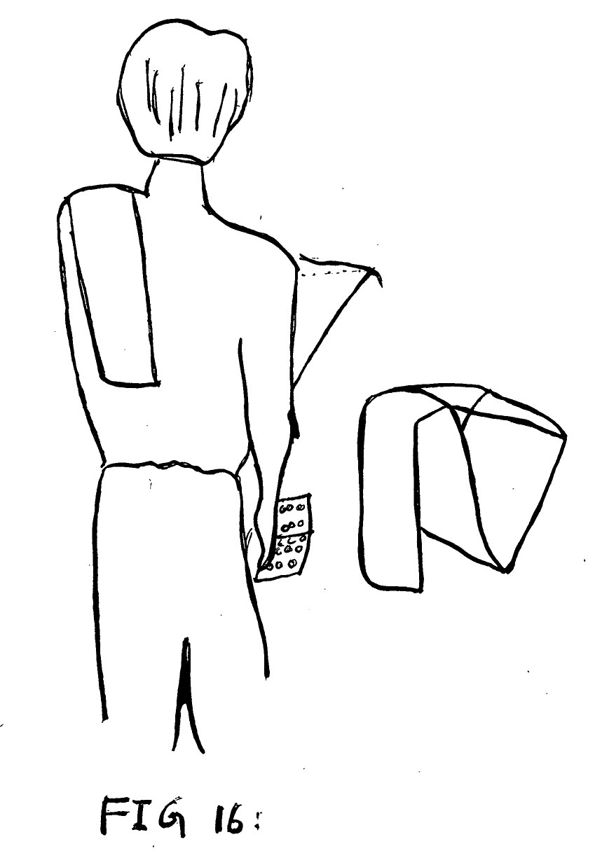

Referring FIG. 16 is a back view of a man wearing an alternate embodiment of the hands free wearable computer that can be carried only close to wearer's chest. If a wearer needs a counterbalancing weight to help with the balance, it can be added to the back of the wearer to this alternate embodiment. A small PDA could be the display in the display tray.

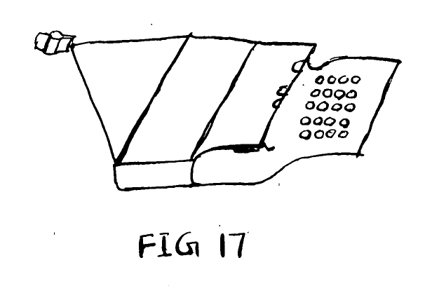

Referring FIG. 17 is a perspective view from right side of a right hand grip and carry hands free integrated input device an alternate embodiment of the input device. The alternate embodiment does not include the side surface.

While this invention has been described in terms of several preferred embodiments, there are alterations, modifications, permutations, and substitute equivalents, which fall within the scope of this invention. It should also be noted that there are many alternative ways of implementing the methods and apparatuses of the present invention. It is therefore intended that the following appended claims be interpreted as including all such alterations, permutations, and substitute equivalents as fall within the true spirit and scope of the present invention.

What is claimed is:

1) A hands free wearable computer, the said hands free wearable computer comprising of a display tray, the said hands free wearable computer comprising of a grip and carry foldable hands free two-hand integrated input device, the said hands free wearable computer comprising a detached or fixed display, the said hands free wearable computer comprising a belt and suspender body harness attached to the said display tray, the said display tray comprises of a one eyed pulley to the left hand top corner of the said display tray.

2) An apparatus as claimed in claim 1, wherein said display tray comprises of a hollow area to insert the said detached or fixed display.

3) An apparatus as claimed in claim 1, wherein said display tray comprises of two bendable flaps attached to the back of the said display tray.

4) An apparatus as claimed in claim 3, wherein said two bendable flaps comprising a multiplicity of Velcro straps to attach the said grip and carry foldable hands free two-hand integrated input device, the said two bendable flaps comprising holes on the outside right and outside left of the said display tray.

5) An apparatus as claimed in claim 1, wherein said display tray comprises of a multiplicity of cloth loops on the outside right and the outside left of the said display tray to help secure the said detached display.

6) An apparatus as claimed in claim 1, wherein said belt and suspender body harness attached to the display tray comprises the suspender front attached to the front left of the belt and suspender back attached to the back left of the belt.

7) An apparatus as claimed in claim 1, wherein said belt and suspender body harness attached to the display tray comprises a small rope passing through the said one eyed pulley to the left hand top corner and is attached to the said display tray at the top right hand corner, the said belt and suspender body harness attached to the display tray comprises a small rope clip with a closed opening sewn to the front middle of the said suspender, the said small rope is guided through the said small rope clip with a closed opening sewn.

8) An apparatus as claimed in claim 1, wherein said display tray comprises of a miniature video camera fixed to the middle of the topside of the said display tray.

9) An apparatus as claimed in claim 1, wherein said belt and suspender body harness attached to the display tray comprises a sliding length wise loop that slides around the belt, the said sliding length wise loop that slides around the belt comprises a cloth handle, the said sliding length wise loop that slides around the belt comprises a cloth loop attached to the top that is used to attach the said cloth loop with the said display tray.

10) An apparatus as claimed in claim 1, wherein said belt and suspender body harness attached to the display tray comprises two cloth snaps attached to the front right middle and front left middle of the said belt to secure the said display tray to the said belt.

11) An apparatus as claimed in claim 1, wherein said belt and suspender body harness attached to the display tray comprises a large rope that is fixed to the top right of the said display tray.

12) An apparatus as claimed in claim 1, wherein said grip and carry foldable hands free two-hand integrated input device comprises two nearly symmetrical grip and carry foldable hands free integrated input devices one to be used with right hand a right hand grip and carry foldable hands free integrated input device and another to be used with the left hand a left hand grip and carry foldable hands free integrated input device.

13) An apparatus as claimed in claim 12, wherein said right hand grip and carry foldable hands free integrated input device comprises a bottom surface and a side surface.

14) An apparatus as claimed in claim 13, wherein said bottom surface and the side surface comprising two wrist pads an inch high, two inch wide and four to five inches long and half inch shorter than the length of the bottom and side surface.

15) An apparatus as claimed in claim 14, wherein said wrist pads are attached to the top of the bottom surface and the side surface such that the bottom surface and the side surface can be folded together.

16) An apparatus as claimed in claim 14, wherein said bottom surface and the side surface are at the same level as the bottom surface of the said wrist pad for one inch on the wide side of the wrist pad, and curve up to reach the one inch height of the top side of the said wrist pad.

17) An apparatus as claimed in claim 16, wherein said portion of the bottom surface and the side surface that curves up is flexible to be adjusted to increase the curvature of the said surface and flexible to be adjusted to increase the height of the far end of the said surface that curves up.

18) An apparatus as claimed in claim 14, wherein said wrist pads comprise a lining of two cm thick and one inch wide and as long as the said bottom and side surfaces is parallel to the contours of the said bottom surface and the said side surface.

19) An apparatus as claimed in claim 14, wherein said wrist pads comprise a chamber for a wireless enable embedded input device computer.

20) An apparatus as claimed in claim 19, wherein said chamber for a wireless enable embedded input device computer comprises a wireless enabled embedded input device computer that can send input data from the said grip and carry foldable hands free two-hand integrated input device to any display device connected to a wireless device.

21) An apparatus as claimed in claim 1, wherein said display device is wireless enabled to receive input data from any wireless input device.

22) An apparatus as claimed in claim 13, wherein said bottom surface comprises an optical mouse input device.

23) An apparatus as claimed in claim 16, wherein said portion of the bottom surface and the side surface that curves up comprises of a plurality of input keys with the said right hand grip and carry foldable hands free integrated input device bottom surface comprises of a plurality of QWERTY/DVOKAK input keys for the right hand and likewise for the left hand, while the side surface comprises of other input keys for entertainment remote controls, number pads etc.

24) An apparatus as claimed in claim 20, wherein said wireless enabled embedded input device computer comprises of a lcd display that displays the computer image and the name of the display device to which the said grip and carry foldable hands free two-hand integrated input device is sending input data and the said lcd display is on the bottom of side surface that can be viewed by a user by tilting the said right hand grip and carry foldable hands free integrated input device.

25) An apparatus as claimed in claim 16, wherein said portion of the bottom surface and the side surface that curves up comprises a clickable scroll wheel on the said bottom surface near the intersection of the said bottom surface and the said side surface where the said clickable scroll wheel operates in two modes that are controlled by a clickable scroll wheel control input key right below the said clickable scroll wheel, where pressing the said clickable scroll wheel control input key switches the destination of the input data of the said clickable scroll wheel between the said display device and the said wireless enabled embedded input device computer.

26) A method of switching the destination of the input data to any wireless enabled display device in a wired and wireless neighborhood by first toggling the control of the clickable scroll wheel as claimed in claim 16 to control the said wireless enabled embedded input device computer that shows in the said lcd display a scrolling display of display devices in the wireless neighborhood, and selecting a display device of interest by clicking the said clickable scroll wheel when the said lcd displays a display device of interest by authenticating the said wireless enabled embedded input device computer to the said selected display device.

27) An apparatus as claimed in claim 18, wherein said lining of two cm thick and one inch wide comprises an input key for space bar on the top surface of the said lining and a plurality of mouse buttons on the bottom surface of the said lining.

28) An apparatus as claimed in claim 18, wherein said lining of two cm thick and one inch wide reaches the top of the said side surface comprises a flat tab of two inch length, one inch wide and a quarter inch.

29) An apparatus as claimed in claim 18, wherein said flat tab of two inch length, one inch wide and a quarter inch comprises input keys for a game controller.

30) An apparatus as claimed in claim 14, wherein said wrist pad on the said bottom surface comprises two connecting cords that are joined together a few inches above to a top clip.

31) An apparatus as claimed in claim 30, wherein said two connecting cords that are joined together a few inches above to a top clip comprise of two bottom clips at the two ends of the said two connecting cords to secure the said grip and carry foldable hands free integrated input device can be secured to the said belt with the said top clip and the said two bottom clips are used to secure one of the said integrated input device to a wearers clothing to keep the said wearer's hands free when the said wearer is not using hands to enter input.

32) An apparatus as claimed in claim 14, wherein said wrist pads comprise a USB port to connect the said grip and carry foldable hands free integrated input device to a display device with wires.

33) A car stand to secure the said grip and carry foldable hands free two-hand integrated input device as claimed in claim 1 above the steering wheel.

34) A chair clip to secure the said belt and suspender body harness attached to the display tray to secure the said display device as claimed in claim 1.

35) An apparatus as claimed in claim 14, wherein said wrist pads comprise of a bristle top surface to prevent depression of nerves on wrists.
